(19) United States
(12) Patent Application Publication
(10) Pub. No.: US 2018/0108853 A1
(43) Pub. Date: Apr. 19, 2018

(54) DISPLAY DEVICE

(71) Applicant: Japan Display Inc, Minato-ku (JP)

(72) Inventor: Heisuke KANAYA, Minato-ku (JP)

(73) Assignee: Japan Display Inc., Minato-ku (JP)

(21) Appl. No.: 15/782,139

(22) Filed: Oct. 12, 2017

(30) Foreign Application Priority Data
Oct. 18, 2016 (JP) 2016-204664

(51) Int. Cl. H01L 51/00; H01L 51/52; G02F 1/1333; G09F 9/30; H05K 1/11; H05K 1/18

(52) U.S. Cl. CPC H01L 51/0097; H01L 51/5253; G02F 1/133308; H01L 27/32; H05K 1/118; H05K 1/189; H01L 2251/566; G09F 9/30

(57) ABSTRACT

A display device includes: a flexible substrate; a plurality of stacked bodies that are formed on the flexible substrate; and a plurality of sealing layers that seal the plurality of stacked bodies, respectively. Each of the plurality of stacked bodies includes a lower electrode, an upper electrode, and alight-emitting layer interposed between the lower and upper electrodes to configure at least one light-emitting element. The adjacent sealing layers are separated with a space interposed therebetween. The upper electrode sealed by each of the plurality of sealing layers is separated from the upper electrode sealed by the adjacent sealing layer with the space interposed therebetween.

### CROSS-REFERENCE TO RELATED APPLICATION

The present application claims priority from Japanese application JP2016-204664 filed on Oct. 18, 2016, the content of which is hereby incorporated by reference into this application.

### BACKGROUND OF THE INVENTION

### 1. Field of the Invention

The present invention relates to a display device.

### 2. Description of the Related Art

In recent years, sheet displays bendable using illuminants such as organic light emitting diodes (OLEDs) have been developed (see JP2011-227369A). Since organic light emitting diodes are easily affected by water, the organic light emitting diodes are covered with sealing films (JP2013-105144A). To improve a barrier property, there is known a sealing film that has a structure in which an organic film is interposed between a pair of inorganic films.

Since hardness of an organic films is different from hardness of inorganic films, allowable radii of curvature are different. Therefore, exfoliation occurs in interfaces or hard inorganic films crack. Thus, there is a problem that sealing performance of sealing films degrades. JP2012-216338A and JP2006-294490A disclose that grooves are formed in insulation layers, but the insulation layers are not sealing layers.

### SUMMARY OF THE INVENTION

An object of the invention is to prevent sealing performance of a sealing layer from degrading.

According to an aspect of the invention, there is provided a display device including: a flexible substrate; a plurality of stacked bodies that are formed on the flexible substrate; and a plurality of sealing layers that seal the plurality of stacked bodies, respectively. Each of the plurality of stacked bodies includes a lower electrode, an upper electrode, and alight-emitting layer interposed between the lower and upper electrodes to configure at least one light-emitting element. The adjacent sealing layers are separated with a space interposed therebetween. The upper electrode sealed by each of the plurality of sealing layers is separated from the upper electrode sealed by the adjacent sealing layer with the space interposed therebetween.

According to the aspect of the invention, the sealing performance of the sealing layer can be prevented from degrading since the flexible substrate is bendable in a space between sealing layers adjacent to each other without producing stress in the sealing layers.

### BRIEF DESCRIPTION OF THE DRAWINGS

FIG. 1A is a perspective view illustrating a display device according to a first embodiment of the invention.

FIG. 1B is a diagram illustrating a use state of the display device illustrated in FIG. 1A.

FIG. 2 is an enlarged view illustrating a partially omitted cross-section taken along the line II-II of the display device illustrated in FIG. 1A.

FIG. 3 is an enlarged view illustrating a partially omitted cross-section taken along the line III-III of the display device illustrated in FIG. 1A.

FIG. 4 is a perspective view illustrating a plurality of lower electrodes and light-emitting layers.

FIG. 5 is a perspective view illustrating a plurality of upper electrodes.

FIG. 6 is a perspective view illustrating a plurality of sealing layers.

FIG. 7 is a sectional view illustrating a display device according to a second embodiment of the invention.

FIG. 8 is a perspective view illustrating a plurality of sealing layers of the display device according to the second embodiment of the invention.

FIG. 9 is a perspective view illustrating a use state of a display device according to a third embodiment of the invention.

FIG. 10 is a perspective view illustrating a plurality of upper electrodes of the display device according to the third embodiment of the invention.

FIG. 11 is a perspective view illustrating a plurality of sealing layers of the display device according to the third embodiment of the invention.

FIG. 12 is a perspective view illustrating a use state of a display device according to a fourth embodiment of the invention.

FIG. 13 is a perspective view illustrating a plurality of upper electrodes of the display device according to the fourth embodiment of the invention.

FIG. 14 is a perspective view illustrating a plurality of sealing layers of the display device according to the fourth embodiment of the invention.

FIG. 15 is a perspective view illustrating a use state of a display device according to a fifth embodiment of the invention.

FIG. 16 is a perspective view illustrating a plurality of upper electrodes of the display device according to the fifth embodiment of the invention.

FIG. 17 is a perspective view illustrating a plurality of sealing layers of the display device according to the fifth embodiment of the invention.

FIG. 18 is a perspective view illustrating a plurality of sealing layers of a display device according to a sixth embodiment of the invention.

FIG. 19 is a sectional view illustrating a display device according to the sixth embodiment of the invention.

FIG. 20 is a perspective view illustrating a plurality of sealing layers of the display device according to a seventh embodiment of the invention.

FIG. 21 is a sectional view illustrating the display device according to the seventh embodiment of the invention.

FIG. 22 is a plan view illustrating a plurality of sealing layers of a display device according to an eighth embodiment of the invention.

FIG. 23 is a plan view illustrating a plurality of sealing layers of a display device according to a ninth embodiment of the invention.

### DETAILED DESCRIPTION OF THE INVENTION

Hereinafter, embodiments of the invention will be described with reference to the drawings. Here, the invention can be embodied according to various aspects within the scope of the invention without departing from the gist of the invention and is not construed as being limited to content described in the embodiments exemplified below.

The drawings are further schematically illustrated in widths, thickness, shapes, and the like of units than actual forms to further clarify description in some cases, but are merely examples and do not limit interpretation of the invention. In the present specification and the drawings, the same reference numerals are given to elements having the same functions described in the previously described drawings and the repeated description will be omitted.

Further, in the detailed description of the invention, “above” and “below” in definition of positional relations of certain constituents and other constituents includes not only a case in which a constituent is located immediately above or immediately below a certain constituent but also a case in which another constituent is interposed between constituents unless otherwise mentioned.

### First Embodiment

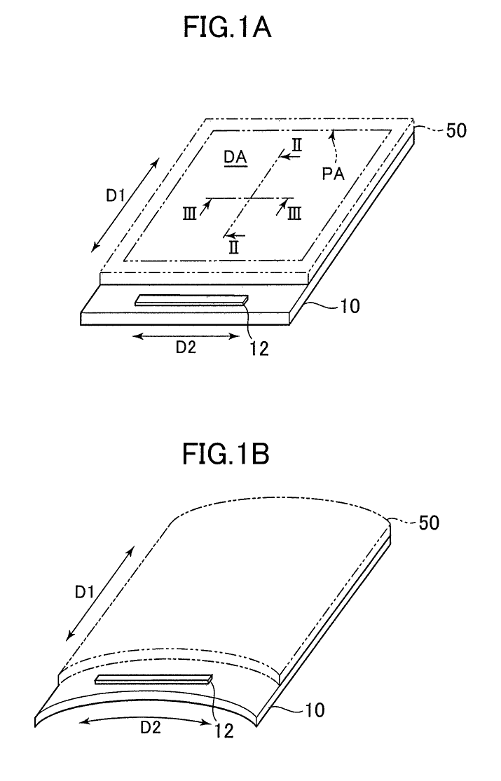

FIG. 1A is a perspective view illustrating a display device according to a first embodiment of the invention.

An organic electroluminescence display device will be exemplified as the display device. The display device is configured to display a full-color image by combining a plurality of pixels (subpixels) of, for example, red, green, and blue. The display device includes a flexible substrate 10. The flexible substrate 10 has a rectangular (for example, oblong) external shape. The flexible substrate 10 includes a display region DA in which a plurality of pixels are arrayed in a matrix form and a peripheral region PA surrounding the display region DA. An integrated circuit chip 12 driving elements to display an image is mounted on the flexible substrate 10 and a flexible printed substrate (not illustrated) may be connected to electrically connect the integrated circuit chip 12 to the outside.

FIG. 1B is a diagram illustrating a use state of the display device illustrated in FIG. 1A. The display device is bended or curved for use. The flexible substrate 10 has an oblong external shape and is curved about an axis along long sides. That is, short sides of the flexible substrate 10 are curved.

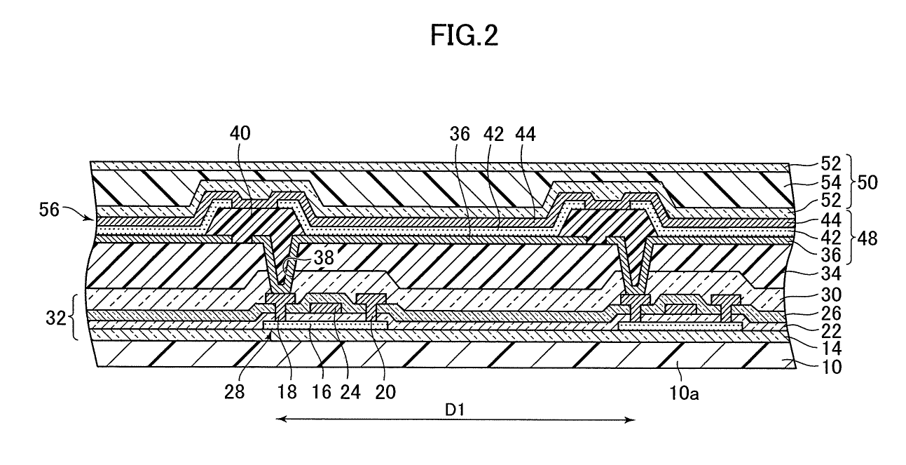

FIG. 2 is an enlarged view illustrating a partially omitted cross-section taken along the line II-II of the display device illustrated in FIG. 1A. The flexible substrate 10 is formed of a polyimide resin, polyethylene terephthalate or the like. In the flexible substrate 10, an undercoat layer 14 serving as a barrier against impurities contained in the flexible substrate 10 is formed. The undercoat layer 14 is formed of, for example, a silicon oxide film or a silicon nitride film or may have a stacked structure of a silicon oxide film and the silicon nitride film. A semiconductor layer 16 is formed above the undercoat layer 14. A source electrode 18 and a drain electrode 20 are electrically connected to the semiconductor layer 16 and a gate insulation film 22 is formed to cover the semiconductor layer 16. A gate electrode 24 is formed above the gate insulation film 22 and an inter-layer insulation film 26 is formed to cover the gate electrode 24. The source electrode 18 and the drain electrode 20 penetrate through the gate insulation film 22 and the inter-layer insulation film 26. A thin film transistor 28 including the semiconductor layer 16, the source electrode 18, the drain electrode 20, and the gate electrode 24 is configured. A passivation film 30 is formed to cover the thin film transistor 28. On the flexible substrate 10, a circuit layer 32 including the thin film transistor 28 is stacked. The circuit layer 32 also reaches the peripheral region PA (see FIG. 1A).

A planarized layer 34 is formed above the passivation film 30. Above the planarized film 34, a plurality of lower electrodes 36 (for example, an anode) are formed to correspond to the plurality of pixels (subpixels), respectively. The planarized layer 34 is formed so that surfaces on which at least the lower electrodes 36 are formed are planarized. As the planarized layer 34, an organic material such as a photosensitive acrylic resin is used in many cases. The lower electrode 36 is electrically connected to one of the source electrode 18 and the drain electrode 20 above the semiconductor layer 16 by a contact hole 38 penetrating through the planarized layer 34 and the passivation film 30.

An insulation layer 40 is formed above the planarized layer 34 and the lower electrode 36. The insulation layer 40 is straddled on a peripheral portion of the lower electrode 36 and is formed to open apart (for example, a middle portion) of the lower electrode 36. A bank surrounding a part of the lower electrode 36 is formed by the insulation layer 40.

A light-emitting layer 42 is formed above the lower electrode 36. The light-emitting layer 42 is formed independently (separately) for each lower electrode 36 on the cross-sectional surface illustrated in FIG. 2. In this case, the light-emitting layer 42 emits blue, red, or green light to correspond to each pixel. The color corresponding to each pixel is not limited thereto. For example, yellow or white may be added. The light-emitting layer 42 is formed by, for example, evaporation. Alternatively, the light-emitting layer 42 may be formed across the plurality of pixels on the entire surface covering the display region DA. That is, the light-emitting layer 42 is continuously formed above the insulation layer 40. In this case, the light-emitting layer 42 is formed by coating in accordance with solvent dispersion. In a case in which the light-emitting layer 42 is formed across the plurality of pixels, the light-emitting layer 42 has a configuration in which white is emitted in all of the subpixels and a portion with a desired color wavelength is extracted through a color filter (not illustrated).

An upper electrode 44 (a common electrode or a cathode) is formed above the light-emitting layer 42. The upper electrode 44 is straddled on the insulation layer 40 serving as a bank. On the cross-sectional surface illustrated in FIG. 2, the upper electrode 44 is continuous on the upper side of the mutually adjacent lower electrodes 36. The light-emitting layer 42 is interposed between the lower electrode 36 and the upper electrode 44 and emits light in such a manner that its luminance is controlled by a current flowing between the lower electrode 36 and the upper electrode 44. At least one layer of a hole transport layer and a hole injection layer (neither of which is illustrated) may be formed between the light-emitting layer 42 and the lower electrode 36. At least one layer of an electron transport layer and an electron injection layer (neither of which is illustrated) may be formed between the light-emitting layer 42 and the upper electrode 44.

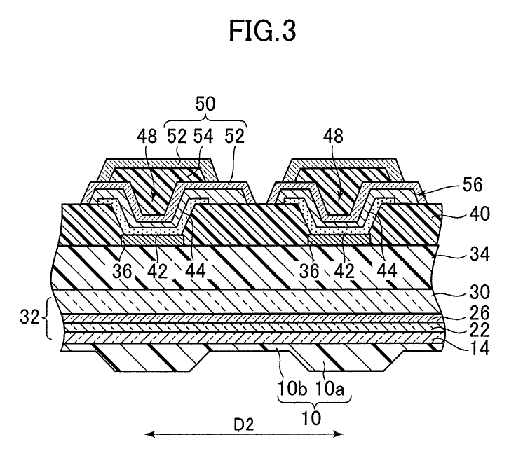

FIG. 3 is an enlarged view illustrating a partially omitted cross-section taken along the line of the display device illustrated in FIG. 1A. On the cross-sectional surface illustrated in FIG. 3, a thick portion 10a and a thin portion 10b of the flexible substrate 10 are illustrated. The thick portion 10a and the thin portion 10b are alternately arranged and extend in one direction (the direction of the line II-II of FIG. 1A). In the flexible substrate 10 illustrated in FIG. 2, only the thick portion 10a is illustrated on the cross-sectional surface. In the thin portion 10b, the flexible substrate 10 is easily bended. The flexible substrate 10 is easily bended about an axis parallel to a line (the line II-II of FIG. 1A) in a direction in which the thin portion 10b extends (a first direction D1).

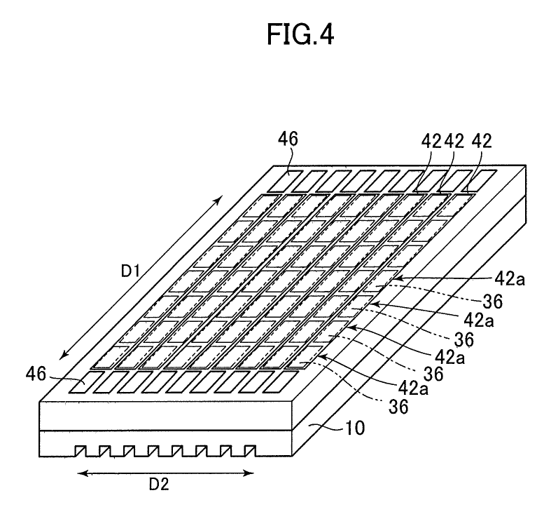

FIG. 4 is a perspective view illustrating a plurality of lower electrodes and light-emitting layers. The plurality of lower electrodes 36 are arranged in the first direction D1 and a second direction D2. The first direction D1 is oriented along an oblong long side which is a planar shape of the flexible substrate 10 and the second direction D2 is oriented along a short side. Contact portions 46 are formed to be adjacent to the plurality of lower electrodes 36 in the first direction D1. Specifically, the contact portions 46 are formed outside on both sides of one group of the lower electrodes 36 arranged in a column in the first direction D1. The contact portions 46 are electrically connected to the circuit layer 32 (see FIG. 2 or 3) in the peripheral region PA (see FIG. 1A).

The plurality of light-emitting layers 42 are formed to overlap the plurality of lower electrodes 36. Specifically, the light-emitting layers 42 are formed to continuously overlap one group of the lower electrodes 36 arranged in a column in the first direction D1. The light-emitting layers 42 extending in the first direction D1 are not straddled on the adjacent lower electrodes 36 in the second direction D2. The light-emitting layers 42 do not overlap the contact portions 46. Carrier transport and injection layer (a hole transport layer, a hole injection layer, an electron transport layer, or an electron injection layer) (not illustrated) may be formed to be separated in the second direction D2 to correspond to the light-emitting layers 42.

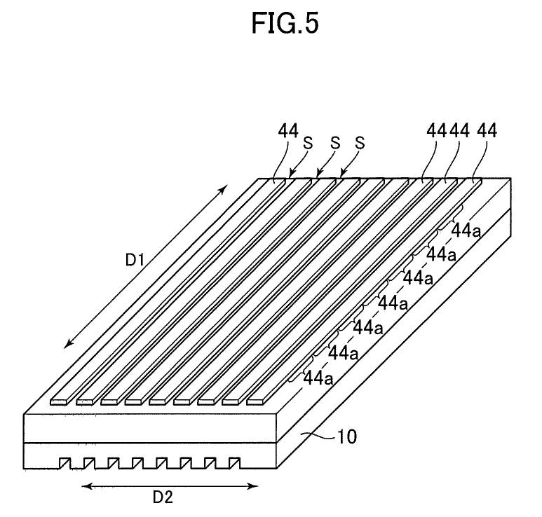

FIG. 5 is a perspective view illustrating a plurality of upper electrodes. The plurality of upper electrodes 44 overlap the plurality of lower electrodes 36 and the plurality of light-emitting layers 42 (see FIG. 4). Specifically, the upper electrodes 44 are formed to continuously overlap one group of the lower electrodes 36 arranged in a column in the first direction D1. The upper electrodes 44 are not straddled on the adjacent lower electrodes 36 in the second direction D2. Each upper electrode 44 is electrically connected to the circuit layer 32 by a pair of contact portions 46 outside on both directions of one group of the lower electrodes 36 arranged in a column in the first direction D1.

One group of light-emitting elements 48 is configured to include each upper electrode 44, the light-emitting layer 42 overlapping the upper electrode 44, and one group of the lower electrodes 36 overlapping the upper electrode 44. Each upper electrode 44 includes a plurality of electrode portions 44a overlapping one group of the lower electrodes 36. As illustrated in FIG. 4, each light-emitting layer 42 includes a plurality of light-emitting portions 42a overlapping one group of the lower electrodes 36. Accordingly, each or one light-emitting element 48 includes one lower electrode 36, one electrode portion 44a, and one light-emitting portion 42a.

As illustrated in FIG. 3, the light-emitting element 48 is covered with a sealing layer 50 stacked on the upper electrode 44 to be sealed, and thus is blocked from water. The sealing layer 50 may have a stacked structure in which at least an inorganic insulation layer 52 formed of, for example, SiN is further included. For example, the sealing layer 50 may have a structure in which at least an organic insulation layer 54 formed of, for example, a resin is interposed between a pair of the inorganic insulation layers 52. One pair of the inorganic insulation layers 52 come into contact to overlap the circumference of the organic insulation layer 54.

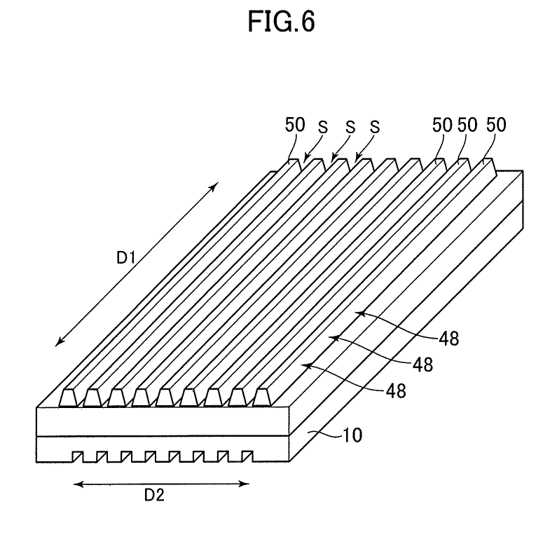

FIG. 6 is a perspective view illustrating a plurality of sealing layers. The plurality of sealing layers 50 seal a plurality of stacked bodies 56 illustrated in FIG. 3, respectively. The stacked body 56 includes the lower electrode 36, the upper electrode 44, and the light-emitting layer 42 interposed between the lower electrode 36 and the upper electrode 44. Specifically, one stacked body 56 includes one upper electrode 44. One upper electrode 44 included in one stacked body 56 includes the plurality of electrode portions 44a (see FIG. 5) and one group of the lower electrodes 36 corresponding to the plurality of electrode portions 44a. In each stacked body 56, one group of the light-emitting elements 48 is arranged along a straight line in the first direction D1. One group of the light-emitting elements 48 is arranged in a row along the straight line in the first direction D1. In the upper electrode 44 included in each of the plurality of stacked bodies 56, the plurality of electrode portions 44a corresponding to one group of the light-emitting elements 48 have a continuous shape.

The sealing layers 50 adjacent in the second direction D2 are separated with a space S interposed therebetween. The space S includes a line-shaped portion extending along a straight line in the first direction D1 across a pair of end portions of the flexible substrate 10. Each of the plurality of sealing layers 50 continuously extends in the straight line in the first direction D1. The straight line in the first direction D1 is parallel to one side of the rectangular shape which is the external shape of the flexible substrate 10. The upper electrode 44 sealed by each of the plurality of sealing layers 50 is separated from the upper electrode 44 sealed by the sealing layer 50 adjacent in the second direction D2 with the space S interposed therebetween, as illustrated in FIG. 5. The upper electrode 44 included in each of the plurality of stacked bodies 56 is electrically connected to the circuit layer 32 (see FIG. 2 or 3) at both end portions along the straight line in the first direction D1. The circuit layer 32 is below the plurality of stacked bodies 56. A direction in which the space S extends, that is, the first direction D1 illustrated in FIG. 5, is preferably a direction intersecting a direction in which the flexible substrate 10 is curved (the second direction D2: see FIG. 1B). According to the embodiment, since the flexible substrate 10 is bendable in the space S between the adjacent sealing layers 50 without producing stress in the sealing layers 50, it is possible to prevent sealing performance of the sealing layers 50 from degrading.

### Second Embodiment

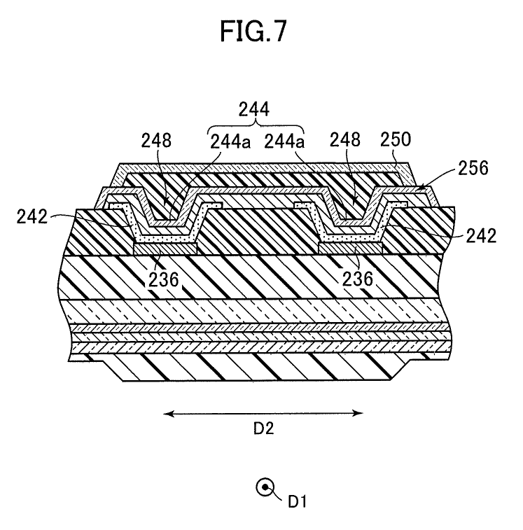

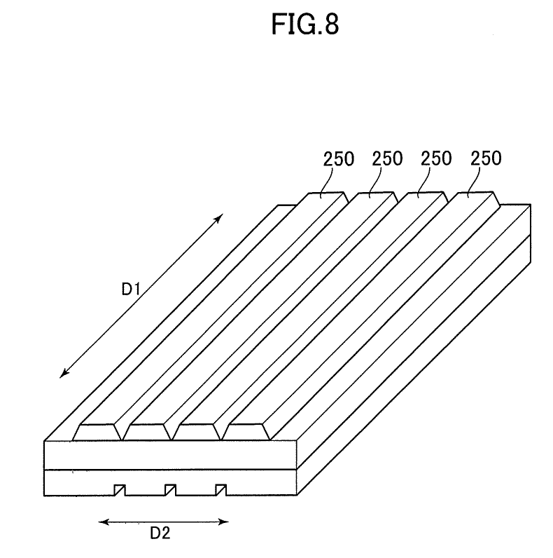

FIG. 7 is a sectional view illustrating a display device according to a second embodiment of the invention. FIG. 8 is a perspective view illustrating a plurality of sealing layers of the display device according to the second embodiment of the invention. The embodiment is different from the first embodiment in that a plurality of light-emitting elements 248 are arranged in the straight line in the first direction D1 in each stacked body 256 and in a plurality of rows, as illustrated in FIG. 7. That is, as illustrated in FIG. 7, upper electrodes 244 continuously overlap the plurality of lower electrodes 236 arranged to be adjacent in the second direction D2. The upper electrodes 244 also continuously overlap a plurality of lower electrodes 236 arranged to be mutually adjacent in the first direction D1 (the front and rear surface directions of FIG. 7).

Along the straight line in the first direction D1, each sealing layer 250 seals a plurality of groups of lower electrodes 236 arranged in a plurality of columns, light-emitting layers 242 corresponding to the one group of lower electrodes 236 arranged in each column in the first direction D1, and the upper electrode 244 overlapping all the plurality of groups of lower electrodes 236. Each upper electrode 244 integrally includes a plurality of groups of electrode portions 244a arranged in a plurality of columns to correspond to a plurality of groups of lower electrodes 236 arranged in a plurality of columns.

### Third Embodiment

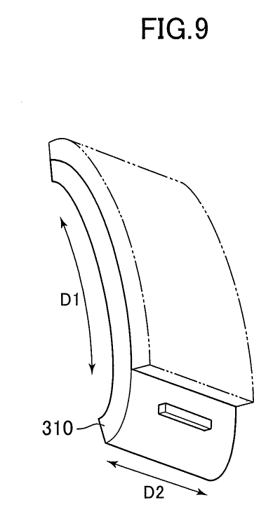

FIG. 9 is a perspective view illustrating a use state of a display device according to a third embodiment of the invention. The embodiment is different from the first or second embodiment in a bending direction of a flexible substrate 310. That is, the flexible substrate 310 is curved about an axis along its short side and a long side is curved.

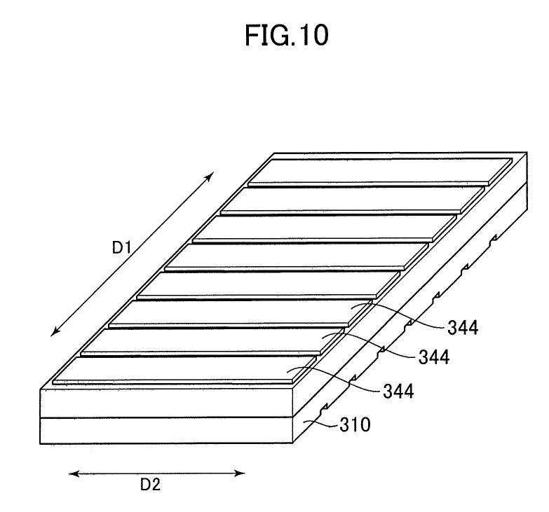

FIG. 10 is a perspective view illustrating a plurality of upper electrodes of the display device according to the third embodiment of the invention. A plurality of upper electrodes 344 extend in the second direction D2 along the short side and the adjacent upper electrodes 344 are arranged in the first direction D1 along the long side.

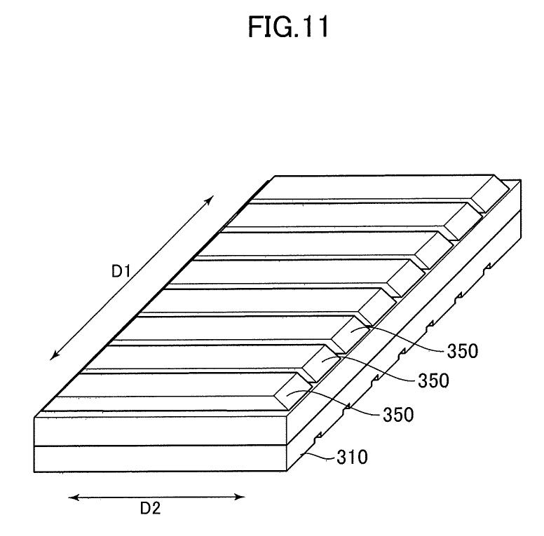

FIG. 11 is a perspective view illustrating a plurality of sealing layers of the display device according to the third embodiment of the invention. A plurality of sealing layers 350 extend in the second direction D2 along the short side and the adjacent sealing layers 350 are arranged in the first direction D1 along the long side.

In the embodiment, the content in which the first direction D1 and the second direction D2 in the first or second embodiment are interchanged one another has been described.

### Fourth Embodiment

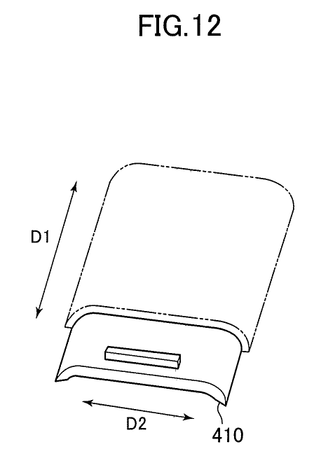

FIG. 12 is a perspective view illustrating a use state of a display device according to a fourth embodiment of the invention. In the embodiment, in a flexible substrate 410, end portions of lateral sides extending along long sides are curved at both end portions of short sides. The end portions are curved about an axis in the first direction D1 along the long sides. Therefore, the short sides are curved. The flexible substrate 10 is flat in the middles of the widths of the short sides.

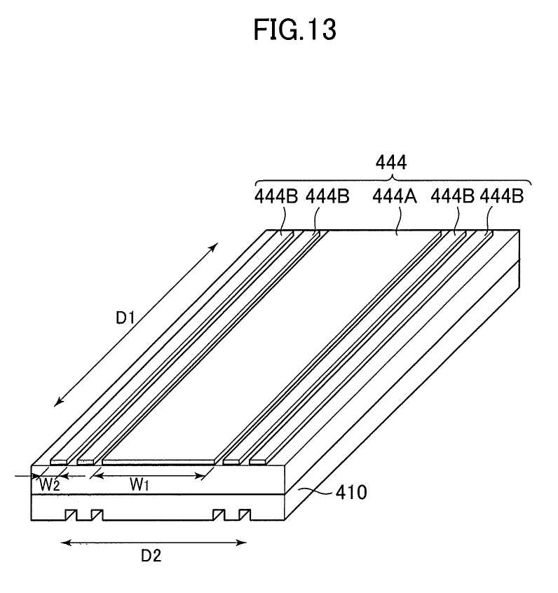

FIG. 13 is a perspective view illustrating a plurality of upper electrodes of the display device according to the fourth embodiment of the invention. A plurality of upper electrodes 444 include a first upper electrode 444A. Below the first upper electrode 444A, the plurality of lower electrodes 36 (see FIG. 4) are arranged in a first number of columns (for example, a many number of columns) along the straight line in the first direction D1. The first upper electrode 444A is in the middle of the flexible substrate 410 in the second direction D2.

The plurality of upper electrodes 444 include second upper electrodes 444B. Below the second upper electrodes 444B, the plurality of lower electrodes 36 (see FIG. 4) are arranged in a second number of columns (for example, one column) along the straight line in the first direction D1. The second upper electrodes 444B are at the end portions of the flexible substrate 410 in the second direction D2. The second number of columns is greater than the first number of columns.

All of the first upper electrode 444A and the second upper electrodes 444B extend in the first direction D1 and have widths in the second direction D2. A width W1 of the first upper electrode 444A is greater than a width W2 of the second upper electrode 444B. At least one upper electrode 444B or the plurality of upper electrodes 444B are at both ends of the flexible substrate 10 in the second direction D2.

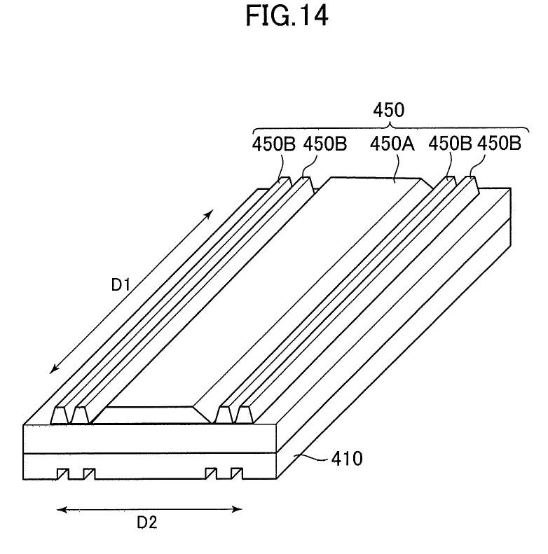

FIG. 14 is a perspective view illustrating a plurality of sealing layers of the display device according to the fourth embodiment of the invention. In a first sealing layer 450A which is at least one of a plurality of sealing layers 450, one group of the light-emitting elements 248 (see FIG. 7) is arranged in a first number of columns (for example, a many number of columns) along the straight line in the first direction D1. In a second sealing layer 450B which is at least another of the plurality of sealing layers 450, one group of the light-emitting elements 48 (see FIG. 3) is arranged in a second number of columns (for example, one column) along the straight line in the first direction D1. The first number of columns is greater than the second number of columns. The first sealing layer 450A is at a position closer to the middle of the flexible substrate 10 in the second direction D2 than the second sealing layer 450B.

### Fifth Embodiment

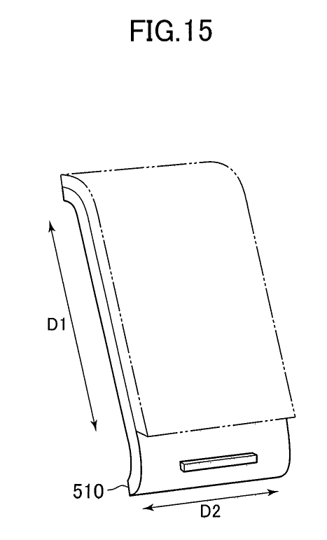

FIG. 15 is a perspective view illustrating a use state of a display device according to a fifth embodiment of the invention. In the embodiment, the content in which the first direction D1 and the second direction D2 in the fourth embodiment are interchanged one another has been described. That is, in a flexible substrate 510, end portions of lateral sides extending along short sides are curved on both sides of the long sides. The end portions are curved about an axis in the second direction D2 along the short sides. Therefore, the long sides are curved. The flexible substrate 510 is flat in the middles of the lengths of the long sides.

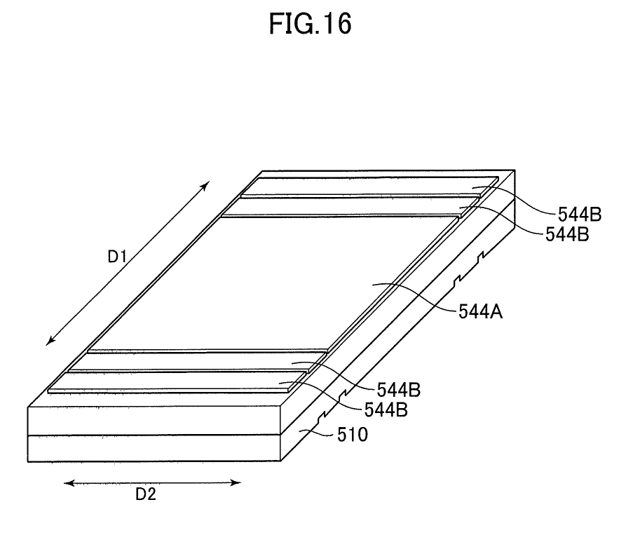

FIG. 16 is a perspective view illustrating a plurality of upper electrodes of the display device according to the fifth embodiment of the invention. A first upper electrode 544A is in the middle of the flexible substrate 510 in the first direction D1. Second upper electrodes 544B are at both end portions of the flexible substrate 510 in the first direction D1. All of the first upper electrode 544A and the second upper electrodes 544B extend in the second direction D2 and have widths in the first direction D1.

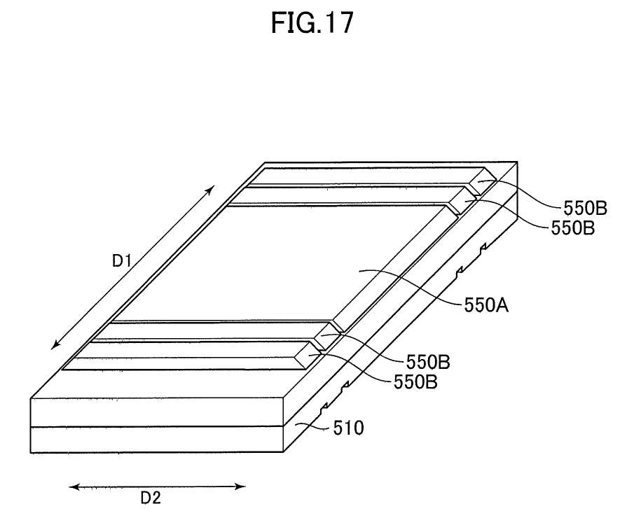

FIG. 17 is a perspective view illustrating a plurality of sealing layers of the display device according to the fifth embodiment of the invention. A first sealing layer 550A is at a position closer to the middle of the flexible substrate 510 in the first direction D1 than a second sealing layers 550B. The other details correspond to the content in which the first direction D1 and the second direction D2 in the fourth embodiment are interchanged one another.

### Sixth Embodiment

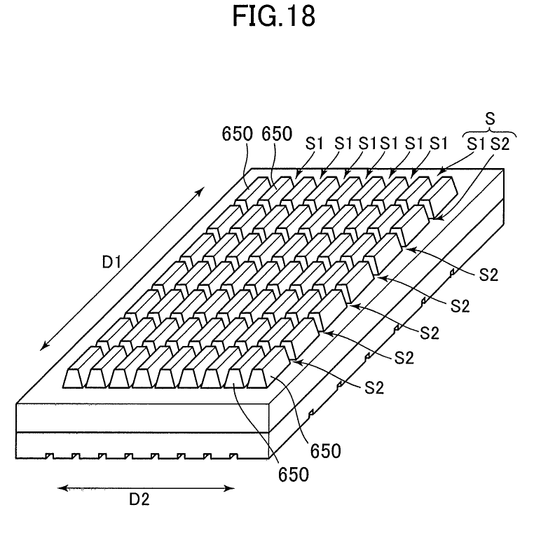

FIG. 18 is a perspective view illustrating a plurality of sealing layers of a display device according to a sixth embodiment of the invention. A space S of adjacent sealing layers 650 includes a first space S1 extending along the straight line in the first direction D1. The space S of the adjacent sealing layers 650 includes a second space S2 extending along the straight line in the second direction D2. That is, the plurality of sealing layers 650 are arranged to be separated in a plurality of rows and a plurality of columns by the first space S1 and the second space S2.

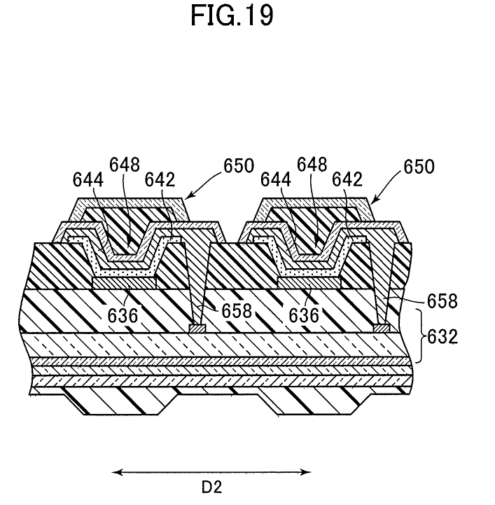

FIG. 19 is a sectional view illustrating a display device according to the sixth embodiment of the invention. One light-emitting element 648 is sealed by one sealing layer 650. That is, each sealing layer 650 seals a lower electrode 636 of each pixel, an upper electrode 644 of each pixel, and a light-emitting layer 642 of each pixel between the lower electrode 636 and the upper electrode 644. In each sealing layer 650, the upper electrode 644 is electrically connected to a circuit layer 632 via a contact 658.

### Seventh Embodiment

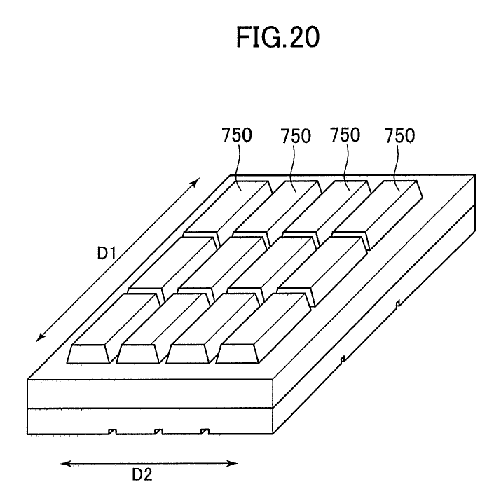

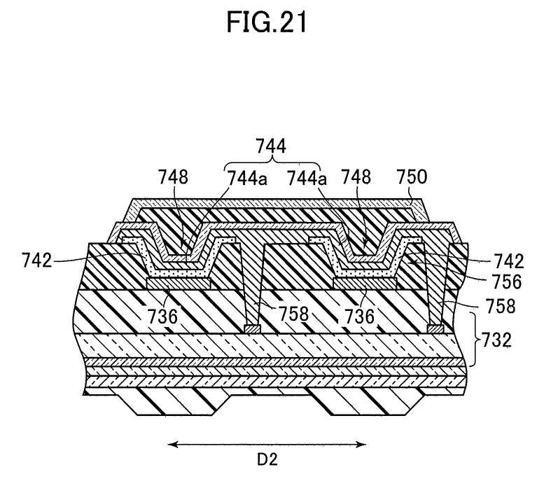

FIG. 20 is a perspective view illustrating a plurality of sealing layers of the display device according to the seventh embodiment of the invention. FIG. 21 is a sectional view illustrating the display device according to the seventh embodiment of the invention. The embodiment is different from the sixth embodiment in that each sealing layer 750 seals one group of light-emitting elements 748.

Each stacked body 756 configures one group of the light-emitting elements 748 arranged in a plurality of rows and a plurality of columns in the first direction D1 and the second direction D2. For example, each stacked body 756 includes a plurality of lower electrodes 736 corresponding to a plurality of pixels, a plurality of light-emitting layers 742 corresponding to the plurality of pixels, and an upper electrode 744 corresponding to the plurality of pixels. The upper electrode 744 included in each stacked body 756 has a shape in which a plurality of electrode portions 744a corresponding to one group of the light-emitting elements 748 are continuous. The upper electrode 744 included in each stacked body 756 is electrically connected to each circuit layer 732 by the plurality of electrode portions 744a to correspond to one group of the light-emitting elements 748. That is, in each stacked body 756, the upper electrode 744 in which the plurality of electrode portions 744a are integrated is electrically connected to the circuit layer 732 by a plurality of contacts 758.

### Eighth Embodiment

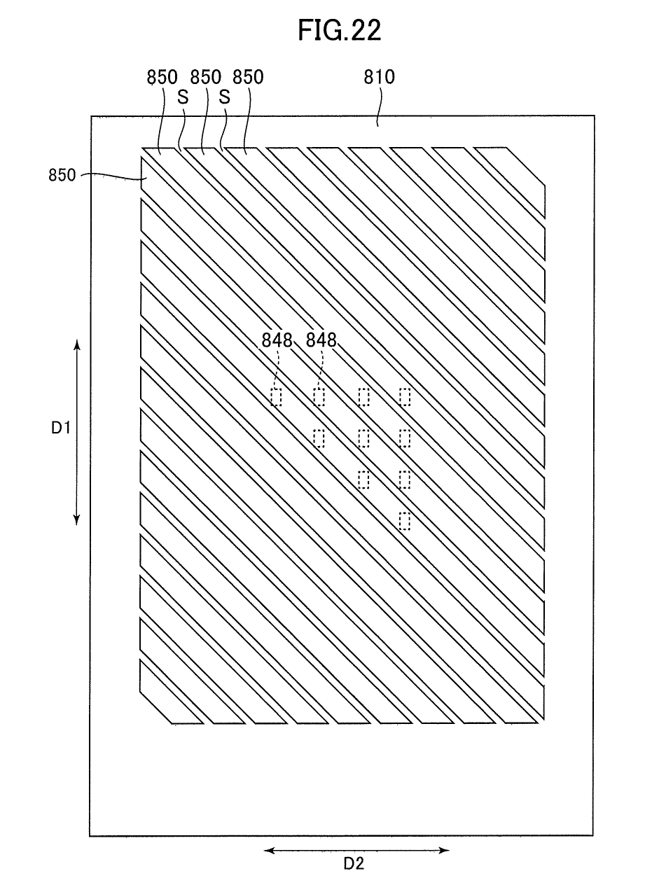

FIG. 22 is a plan view illustrating a plurality of sealing layers of a display device according to an eighth embodiment of the invention. The embodiment is different from the first embodiment in that straight lines extending along spaces S between adjacent sealing layers 850 intersect either side (the first direction D1 and the second direction D2) of a rectangle which is an external shape of a flexible substrate 810. One group of light-emitting elements 848 sealed by each sealing layer 850 is arranged in a column along the straight line. The straight lines intersect sides (the first direction D1 and the second direction D2) of the flexible substrate 810.

### Ninth Embodiment

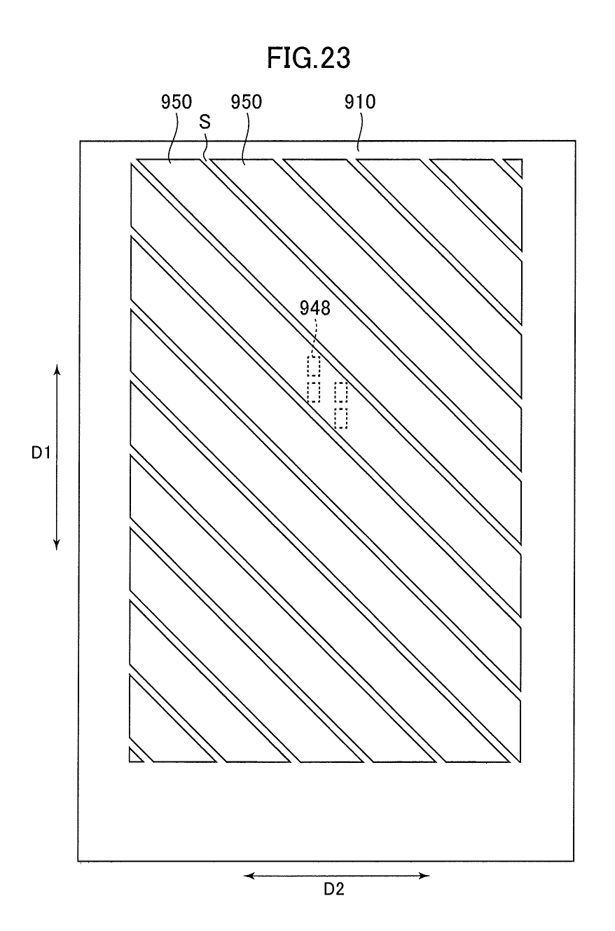

FIG. 23 is a plan view illustrating a plurality of sealing layers of a display device according to a ninth embodiment of the invention. The embodiment is different from the second embodiment in that straight lines extending along spaces S between adjacent sealing layers 950 intersect either side (the first direction D1 and the second direction D2) of a rectangle which is an external shape of a flexible substrate 910. One group of light-emitting elements 948 sealed by each sealing layer 950 is arranged in a plurality of columns along the straight lines. The straight lines intersect sides (the first direction D1 and the second direction D2) of the flexible substrate 910.

The display device is not limited to an organic electroluminescence display device, but a display device in which each pixel includes a light-emitting element such as a quantum-dot light emitting diode (QLED) or a liquid crystal display device may be used.

While there have been described what are at present considered to be certain embodiments of the invention, it will be understood that various modifications may be made thereto, and it is intended that the appended claims cover all such modifications as fall within the true spirit and scope of the invention.

What is claimed is:

1. A display device comprising:
a flexible substrate;
a plurality of stacked bodies that are formed on the flexible substrate; and
a plurality of sealing layers that seal the plurality of stacked bodies, respectively,
wherein each of the plurality of stacked bodies includes a lower electrode, an upper electrode, and a light-emitting layer interposed between the lower and upper electrodes to configure at least one light-emitting element,
wherein the adjacent sealing layers are separated with a space interposed therebetween, and
wherein the upper electrode sealed by each of the plurality of sealing layers is separated from the upper electrode sealed by the adjacent sealing layer with the space interposed therebetween.

2. The display device according to claim 1,
wherein the flexible substrate includes a pair of end portions facing each other, and
wherein the space extends across the pair of end portions.

3. The display device according to claim 2,
wherein the flexible substrate has a rectangular external shape, and
wherein a direction in which the space extends is a direction in which one side of the rectangular shape extends.

4. The display device according to claim 2,
wherein the flexible substrate has a rectangular external shape, and
wherein a direction in which the space extends intersects either side of the rectangular shape.

5. The display device according to claim 1,
wherein the space includes a line-shaped portion extending in a line shape across a pair of end portions of the flexible substrate facing each other,
wherein each of the plurality of sealing layers continuously extends along the line-shaped portion, and
wherein each of the plurality of stacked bodies configures one group of light-emitting elements arranged in the line-shaped portion.

6. The display device according to claim 5,
wherein the upper electrode included in each of the plurality of stacked bodies has a shape in which a plurality of electrode portions corresponding to the group of the light-emitting elements are continuous.

7. The display device according to claim 6, further comprising:
a circuit layer under the plurality of stacked bodies,
wherein the upper electrodes included in each of the plurality of stacked bodies is electrically connected to the circuit layer at both end portions along the line-shaped portion.

8. The display device according to claim 5,
wherein the group of the light-emitting elements is arranged in a column along the line-shaped portion.

9. The display device according to claim 5,
wherein the group of the light-emitting elements is arranged in a plurality of columns along the line-shaped portion.

10. The display device according to claim 5,
wherein in a first sealing layer which is at least one of the plurality of sealing layers, the group of the light-emitting elements is arranged in a first number of columns along the line-shaped portion,
wherein in a second sealing layer which is at least another of the plurality of sealing layers, the group of the light-emitting elements is arranged in a second number of columns along the line-shaped portion, and
wherein the first number of columns is greater than the second number of columns.

11. The display device according to claim 10,
wherein the first sealing layer is located at a position closer to a middle of the flexible substrate than the second sealing layer.

12. The display device according to claim 1,
wherein the space includes a first space extending along a first straight line and a second space extending in a second straight line intersecting the first straight line, and
wherein the plurality of sealing layers are separated by the first and second spaces to be arranged in a plurality of rows and a plurality of columns.

13. The display device according to claim 12,
wherein the flexible substrate has a rectangular external shape,
wherein the first straight line is parallel to one side of the rectangular shape, and
wherein the second straight line is orthogonal to the first straight line.

14. The display device according to claim 12,
wherein each of the plurality of stacked bodies configures one group of light-emitting elements arranged in a plurality of rows and a plurality of columns.

15. The display device according to claim 14,
wherein the upper electrode included in each of the plurality of stacked bodies has a shape in which a plurality of electrode portions corresponding to the group of the light-emitting elements are continuous.

16. The display device according to claim 15, further comprising:
a circuit layer under the plurality of stacked bodies,
wherein the upper electrodes included in each of the plurality of stacked bodies is electrically connected to the circuit layer in a plurality of electrode portions to correspond to the group of the light-emitting elements.

17. The display device according to claim 12,
wherein each of the plurality of stacked bodies configures one light-emitting element.

18. The display device according to claim 17, further comprising:
a circuit layer under the plurality of stacked bodies,
wherein the upper electrodes included in each of the plurality of stacked bodies is electrically connected to the circuit layer.

19. The display device according to claim 1,
wherein the flexible substrate is curved, and
wherein the space extends in a direction intersecting a direction in which the flexible substrate is curved.
